(19) United States
(12) Patent Application Publication
(10) Pub. No.: US 2026/0251721 A1
(43) Pub. Date: Aug. 27, 2026

(54) Apparatus and Method for Diagnosing Battery

(71) Applicant: LG Energy Solution, Ltd., Seoul (KR)

(72) Inventors: A-Ming Cha, Daejeon (KR); Yoon-Jung Bae, Daejeon (KR)

(73) Assignee: LG Energy Solution, Ltd., Seoul (KR)

(21) Appl. No.: 18/865,523

(22) PCT Filed: Sep. 21, 2023
(86) PCT No.: PCT/KR2023/014442

§ 371 Date: Nov. 13, 2024

(30) Foreign Application Priority Data
Sep. 22, 2022 (KR) 10-2022-0119803

(51) Int. Cl. G01R 31/3842; G01R 31/378; H01M 10/42

(52) U.S. Cl. CPC G01R 31/3842; G01R 31/378; H01M 10/4285

(57) ABSTRACT

An apparatus for diagnosing a battery includes a profile obtaining unit configured to obtain a capacity profile for a constant current charging capacity and a constant voltage charging capacity measured in a charging process of a battery, and a control unit configured to calculate a capacity change rate between the constant current charging capacity and the constant voltage capacity charging in the capacity profile, compare the calculated capacity change rate with a preset reference value, and diagnose the state of the battery based on the comparison result.

### CROSS-REFERENCE TO RELATED APPLICATIONS

The present application is a national phase entry under 35 U.S.C. § 371 of International Application No. PCT/KR2023/014442 filed on Sep. 21, 2023, and published as International Publication No. WO2024/063577A1, which claims priority from Korean Patent Application No. 10-2022-0119803 filed on Sep. 22, 2022, all of which are hereby incorporated herein by reference in its entirety.

### TECHNICAL FIELD

The present disclosure relates to an apparatus and method for diagnosing a battery, and more particularly, to an apparatus and method for diagnosing a battery, which is capable of diagnosing a state of a battery.

### BACKGROUND

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Batteries commercially available at present include nickel-cadmium batteries, nickel hydrogen batteries, nickel-zinc batteries, lithium batteries and the like. Among them, the lithium batteries are in the limelight since they have almost no memory effect compared to nickel-based batteries and also have very low self-charging rate and high energy density.

Although much research is being done on the batteries in terms of increasing capacity and density, improvements in lifespan and safety are also important. In order to improve battery safety, technology to accurately diagnose the current state of the battery is required.

For example, it is necessary to prevent lithium precipitation on the surface of the negative electrode (lithium plating, Li-plating). When lithium is precipitated on the surface of the negative electrode, it causes side reactions with the electrolyte and changes in the kinetic balance or the like of the battery, causing battery deterioration. In addition, as lithium metal is precipitated on the surface of the negative electrode, an internal short circuit of the battery may occur, and thus there is a risk of ignition or explosion due to an internal short circuit. Therefore, there is a need to develop technology that can detect whether lithium metal is precipitated on the surface of the negative electrode.

### SUMMARY OF THE INVENTION

### Technical Problem

The present disclosure is designed to solve the problems of the related art, and therefore the present disclosure is directed to providing an apparatus and method for diagnosing a battery, which is capable of quickly diagnosing a current state of a battery.

These and other objects and advantages of the present disclosure may be understood from the following detailed description and will become more fully apparent from the exemplary embodiments of the present disclosure. Also, it will be easily understood that the objects and advantages of the present disclosure may be realized by the means shown in the appended claims and combinations thereof.

### Technical Solution

An apparatus for diagnosing a battery according to one aspect of the present disclosure may comprise a control unit configured to calculate a capacity change rate between a constant current charging capacity of the battery and a constant voltage charging capacity of the battery according to a capacity profile of the battery, wherein the capacity profile indicates, for each charging cycle of a plurality of charging cycles of the battery, a correspondence between the constant current charging capacity of the battery during the charging cycle and the constant voltage charging capacity of the battery during the charging cycle, compare the calculated capacity change rate with a preset reference value, and diagnose the state of the battery based on the comparison of the calculated capacity change rate with the preset reference value.

The control unit may be configured to diagnose the state of the battery as an available lithium loss state, a normal state, or a positive electrode capacity deterioration state based on the comparison of the calculated capacity change rate with the preset reference value.

The control unit may be configured to diagnose the state of the battery as the available lithium loss state, in response to the capacity change rate being less than the reference value.

The control unit may be configured to diagnose the state of the battery as the normal state, in response to the capacity change rate being equal to the reference value.

The control unit may be configured to diagnose the state of the battery as the positive electrode capacity deterioration state, in response to the capacity change rate exceeding the reference value.

The control unit may be configured to classify at least one subset of the capacity profile into a respective capacity section according to a magnitude relationship between the capacity change rate and the reference value, and diagnose the state of the battery for the respective capacity section.

The control unit may be configured to calculate the capacity change rate for each of a plurality of constant current charging capacities included in the at least one subset of the capacity profile, select, from among the plurality of constant current charging capacities included in the capacity profile, a target capacity whose corresponding calculated capacity change rate is equal to the reference value, and classify the subset of the capacity profile based on the selected target capacity.

The control unit may be configured to diagnose the state of the battery as an unusable state, in response to the state of the battery being sequentially diagnosed as the positive electrode capacity deterioration state, the available lithium loss state, and the positive electrode capacity deterioration state.

The control unit may be configured to change a use condition preset for the battery to correspond to the state of the battery.

The control unit may be configured to change at least one of an upper limit of a charging current rate (C-rate) preset for the battery or a rest period, in response to the state of the battery being diagnosed as the available lithium loss state.

The control unit may be configured to change at least one of an upper limit voltage or a maximum allowable temperature preset for the battery, in response to the state of the battery being diagnosed as the positive electrode capacity deterioration state.

The apparatus may further include a memory store configured to store the capacity profile, and the control unit may be configured to receive the capacity profile from the memory store.

A battery pack according to another aspect of the present disclosure may comprise the apparatus for diagnosing a battery according to any of the embodiments described herein. An electric vehicle according to still another aspect of the present disclosure may comprise the apparatus for diagnosing a battery according to one aspect of the present disclosure.

An energy storage system according to still another aspect of the present disclosure may comprise the apparatus for diagnosing a battery according to one aspect of the present disclosure.

A method for diagnosing a battery according to still another aspect of the present disclosure may comprise obtaining a capacity profile, wherein the capacity profile indicates, for each charging cycle of a plurality of charging cycles of the battery, a correspondence between a constant current charging capacity of the battery during the charging cycle and a constant voltage charging capacity of the battery during the charging cycle; calculating a capacity change rate between the constant current charging capacity of the battery and the constant voltage charging capacity of the battery according to the capacity profile of the battery; comparing the calculated capacity change rate with a preset reference value; and diagnosing the state of the battery based on the comparison of the calculated capacity change rate with the preset reference value.

### Advantageous Effects

According to one aspect of the present disclosure, the apparatus for diagnosing a battery is characterized by being able to quickly and specifically diagnose the state of a battery according to the degree of change between a constant current charging capacity and a constant voltage charging capacity.

The effects of the present disclosure are not limited to the effects mentioned above, and other effects not mentioned will be clearly understood by those skilled in the art from the description of the claims.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a diagram schematically showing an apparatus for diagnosing a battery according to an embodiment of the present disclosure.

FIG. 2 is a diagram schematically showing a first capacity profile according to an embodiment of the present disclosure.

FIG. 3 is a diagram comparing a first capacity curve of the first capacity profile and a reference line according to an embodiment of the present disclosure.

FIG. 4 is a diagram to explain a positive electrode capacity deterioration state of a battery according to an embodiment of the present disclosure.

FIG. 5 is a diagram to explain an available lithium loss state of the battery according to an embodiment of the present disclosure.

FIG. 6 is a diagram schematically showing a second capacity profile according to an embodiment of the present disclosure.

FIG. 7 is a diagram comparing a second capacity curve of the second capacity profile and the reference line according to an embodiment of the present disclosure.

FIG. 8 is a diagram schematically showing an exemplary configuration of a battery pack according to another embodiment of the present disclosure.

FIG. 9 is a diagram schematically showing an electric vehicle according to still another embodiment of the present disclosure.

FIG. 10 is a diagram schematically showing an ESS according to still another embodiment of the present disclosure.

FIG. 11 is a diagram schematically showing a method for diagnosing a battery according to still another embodiment of the present disclosure.

### DETAILED DESCRIPTION

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

The terms including the ordinal number such as “first”, “second” and the like, may be used to distinguish one element from another among various elements, but not intended to limit the elements by the terms.

Throughout the specification, when a portion is referred to as “comprising” or “including” any element, it means that the portion may include other elements further, without excluding other elements, unless specifically stated otherwise.

In addition, throughout the specification, when a portion is referred to as being “connected” to another portion, it is not limited to the case that they are “directly connected”, but it also includes the case where they are “indirectly connected” with another element being interposed between them.

Hereinafter, a preferred embodiment of the present disclosure will be described in detail with reference to the accompanying drawings.

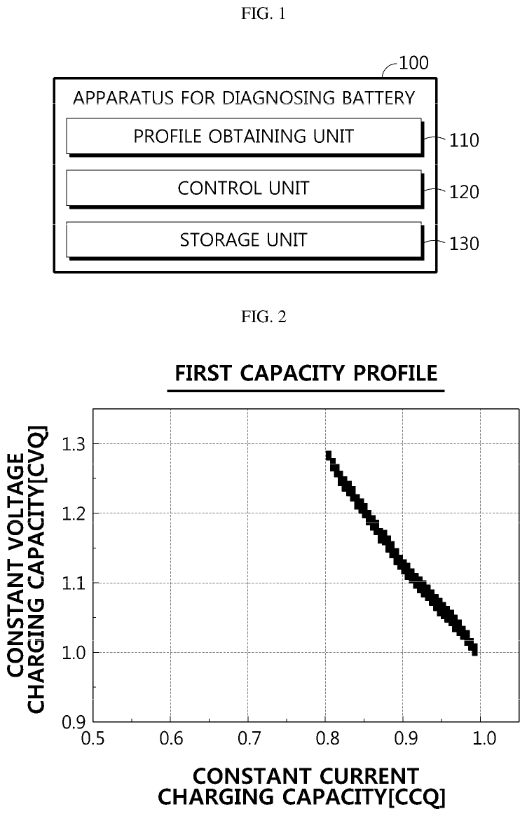

FIG. 1 is a diagram schematically illustrating an apparatus 100 for diagnosing a battery according to an embodiment of the present disclosure.

Referring to FIG. 1, the apparatus 100 for diagnosing a battery may include a profile obtaining unit 110, a control unit 120, and a storage unit 130.

Here, the battery refers to an independent cell that has a negative electrode terminal and a positive electrode terminal and is physically separable. As an example, a lithium-ion battery or a lithium polymer battery may be considered a battery. Additionally, the battery may mean a battery module in which a plurality of cells are connected in series and/or parallel. Below, for convenience of explanation, the battery is explained as meaning one independent cell.

The profile obtaining unit 110 may be configured to obtain a capacity profile for a constant current charging capacity and a constant voltage charging capacity measured in the charging process of the battery.

For example, the profile obtaining unit 110 may receive a capacity profile from the outside using a provided communication module.

As another example, the profile obtaining unit 110 may be connected to the storage unit 130 to perform wired communication and/or wireless communication. The profile obtaining unit 110 may access the storage unit 130 to obtain the capacity profile stored in the storage unit 130.

Specifically, the capacity profile may be a profile accumulated over time and stored in the storage unit 130, and may indicate the corresponding relationship between the constant current charging capacity and the constant voltage charging capacity measured at each charging cycle for the battery. Here, the constant current charging capacity refers to a charging capacity of the battery when the battery is charged with a constant current (CC). Also, the constant voltage charging capacity refers to a charging capacity of the battery when the battery is charged with a constant voltage (CV).

Generally, when explaining the charging process of a battery, the battery is charged with a constant current until the voltage reaches a preset cut-off voltage. In the constant current charging process, the charging current is kept constant, and the voltage of the battery rises in proportion to the current. Also, when the voltage of the battery reaches the cut-off voltage, the battery is charged with a constant voltage. In the constant voltage charging process, the battery voltage is kept constant, and the charging current is gradually reduced. Also, when the charging current reaches the preset cut-off current, battery charging ends.

For example, when a total of 100 charging cycles are performed, the capacity profile may include, for each given cycle of the 100 charging cycles, the corresponding relationship between the constant current charging capacity during the given charging cycle and the constant voltage charging capacity during the given charging cycle.

FIG. 2 is a diagram schematically showing a first capacity profile P1 according to an embodiment of the present disclosure.

Specifically, the first capacity profile P1 is a profile that represents the corresponding relationship between the constant current charging capacity and the constant voltage charging capacity of the first battery. The first capacity profile P1 is a normalized profile based on the constant current charging capacity measured in the first charging cycle of the battery and the first constant voltage charging capacity measured in the first charging cycle of the battery. In one example embodiment, the normalized constant current charging capacity of the battery may be 0.8, and the normalized constant voltage charging capacity may be about 1.28.

The control unit 120 may be configured to calculate the capacity change rate between the constant current charging capacity and the constant voltage charging capacity in the capacity profile.

Specifically, the control unit 120 may calculate the change rate of the constant voltage charging capacity with respect to the constant current charging capacity as a capacity change rate.

For example, the capacity change rate may be an instantaneous change rate or an average change rate of the constant voltage charging capacity with respect to the constant current charging capacity.

In one embodiment, the control unit 120 may calculate an instantaneous change rate between the constant current charging capacity and the constant voltage charging capacity most recently included in the capacity profile. Specifically, the control unit 120 may obtain a capacity curve corresponding to the capacity profile through curve fitting. Also, the control unit 120 may calculate the instantaneous change rate at the desired constant current charging capacity based on the relationship equation of the capacity curve.

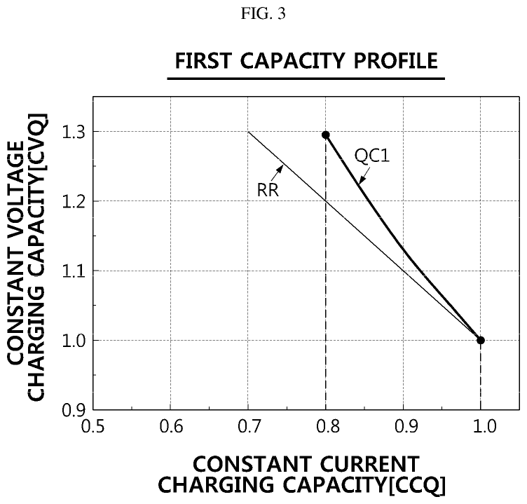

FIG. 3 is a diagram comparing a first capacity curve QC1 of the first capacity profile P1 and a reference line RR according to an embodiment of the present disclosure.

In the embodiment of FIG. 3, the first capacity curve QC1 may be a capacity curve obtained from the first capacity profile P1 using a curve fitting algorithm. The first capacity curve QC1 may represent the corresponding relationship between the constant current charging capacity and the constant voltage charging capacity in the constant current charging capacity section of 0.8 to 1.0.

The control unit 120 may be configured to compare the calculated capacity change rate and a preset reference value.

Preferably, the control unit 120 may compare an absolute value of the calculated capacity change rate and the preset reference value. That is, the capacity change rate calculated by the control unit 120 may be 0 or a positive real value. Hereinafter, for convenience of explanation, note that the comparison between the capacity change rate and the reference value means comparing the absolute value of the capacity change rate and the reference value.

In the embodiment of FIG. 3, it is assumed that the reference line RR is a straight line in which the absolute value of the slope is set as the reference value. For example, the reference value may be preset to 1. Also, the reference line RR may be a straight line with a slope of −1. That is, the absolute value of the slope of the reference line RR and the reference value may be 1.

Specifically, the control unit 120 may compare the magnitude between the calculated capacity change rate and the reference value.

For example, in the embodiment of FIG. 3, the average change rate and the instantaneous change rate of the first capacity curve QC1 may be smaller than the slope of the reference line RR. Therefore, the control unit 120 may determine that the reference value is smaller than the capacity change rate (specifically, the absolute value of the capacity change rate) of the first capacity curve QC1.

The control unit 120 may be configured to diagnose the state of the battery based on the comparison result.

Specifically, the control unit 120 may be configured to diagnose the state of the battery as an available lithium loss state, a normal state, or a positive electrode capacity deterioration state based on the comparison result. That is, the control unit 120 may diagnose the state of the battery as an available lithium loss state, a normal state, or a positive electrode capacity deterioration state based on the magnitude comparison between the reference value and the capacity change rate.

For example, if the capacity change rate is less than the reference value, the control unit 120 may diagnose the state of the battery as an available lithium loss state. As another example, if the capacity change rate is equal to the reference value, the control unit 120 may diagnose the state of the battery as a normal state. As still another example, if the capacity change rate exceeds the reference value, the control unit 120 may diagnose the state of the battery as a positive electrode capacity deterioration state.

For example, in the embodiment of FIG. 3, because the capacity change rate of the first capacity profile P1 exceeds the reference value, the control unit 120 may diagnose the state of the first battery as a positive electrode capacity deterioration state.

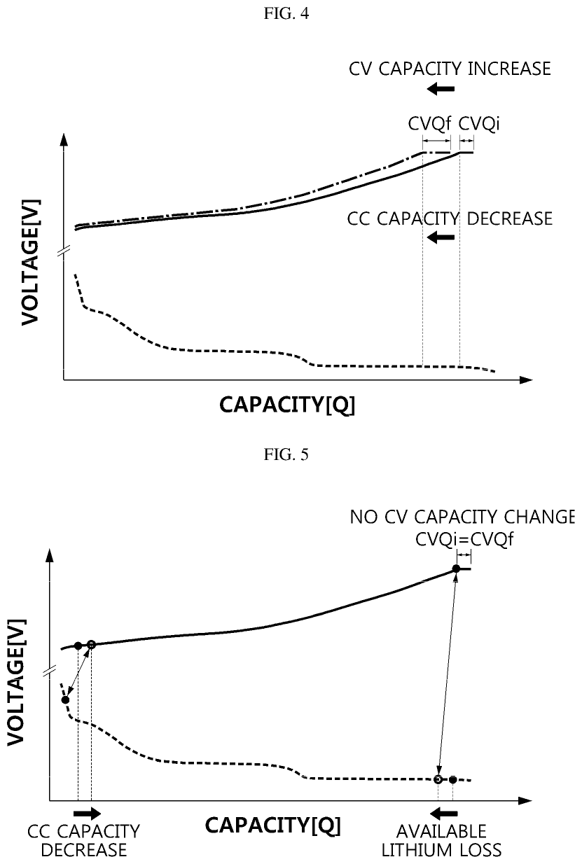

FIG. 4 is a diagram to explain a positive electrode capacity deterioration state of a battery according to an embodiment of the present disclosure.

Referring to FIG. 4, when the positive electrode capacity of the battery is deteriorated, the constant voltage charging capacity (CV capacity) may increase from CVQi to CVQf. Also, the constant current charging capacity (CC capacity) may be reduced. In other words, as the positive electrode capacity is deteriorated, the change rate of the constant voltage charging capacity with respect to the constant current charging capacity may change rapidly. Therefore, if the capacity change rate of the capacity profile exceeds the reference value, the control unit 120 may diagnose the state of the battery as a positive electrode capacity deterioration state.

FIG. 5 is a diagram to explain an available lithium loss state of the battery according to an embodiment of the present disclosure.

Referring to FIG. 5, when the available lithium of the battery is lost, the constant voltage charging capacity (CV capacity) may not change. Also, the constant current charging capacity (CC capacity) may be reduced by the loss of available lithium. In other words, as available lithium is lost, the change rate of the constant voltage charging capacity to the constant current charging capacity may change gradually. Therefore, if the capacity change rate of the capacity profile is less than the reference value, the control unit 120 may diagnose the state of the battery as an available lithium loss state.

The apparatus 100 for diagnosing a battery according to an embodiment of the present disclosure is characterized by being able to quickly and specifically diagnose the state of the battery depending on the degree of change between the constant current charging capacity and the constant voltage charging capacity.

The apparatus 100 for diagnosing a battery may diagnose the state of the battery by considering only the corresponding relationship between the constant current charging capacity and the constant voltage charging capacity without being affected by the charging C-rate (Current rate). Therefore, in situations where there are no restrictions such as low-rate charging (e.g., 0.05 C charging) or data comparison at the same C-rate, the apparatus 100 for diagnosing a battery may quickly diagnose the state of the battery.

Meanwhile, the control unit 120 included in the apparatus 100 for diagnosing a battery may optionally include processors, application-specific integrated circuits (ASICs), other chipsets, logic circuits, registers, communication modems, data processing devices, etc. known in the art to execute various control logics performed in the present disclosure. Also, when the control logic is implemented as software, the control unit 120 may be implemented as a set of program modules. At this time, the program module may be stored in the memory and executed by the control unit 120. The memory may be inside or outside the control unit 120 and may be connected to the control unit 120 by various well-known means.

In addition, the apparatus 100 for diagnosing a battery may further include a storage unit 130. The storage unit 130 may store data necessary for operation and function of each component of the apparatus 100 for diagnosing a battery, data generated in the process of performing the operation or function, or the like. The storage unit 130 is not particularly limited in its kind as long as it is a known information storage means that can record, erase, update and read data. As an example, the information storage means may include random access memory (RAM), flash memory, read-only memory (ROM), electrically erasable programmable read-only memory (EEPROM), registers, and the like. In addition, the storage unit 130 may store program codes in which processes executable by the control unit 120 are defined.

The control unit 120 may be configured to classify the capacity profile into at least one capacity section according to the magnitude relationship between the capacity change rate and the reference value.

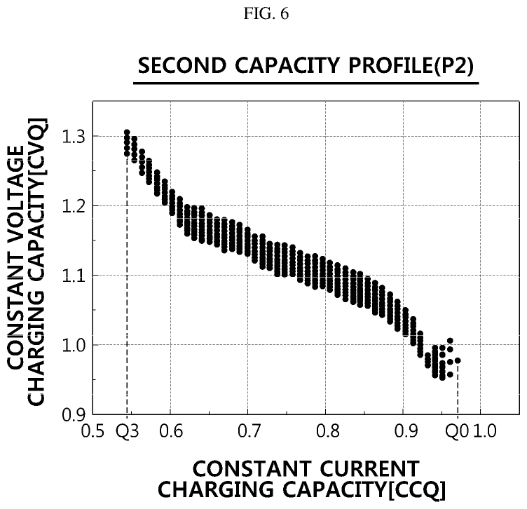

FIG. 6 is a diagram schematically showing a second capacity profile P2 according to an embodiment of the present disclosure.

Specifically, the second capacity profile P2 is a profile that represents the corresponding relationship between the constant current charging capacity and the constant voltage charging capacity of the second battery. The second capacity profile P2 is a profile normalized based on the first constant current charging capacity and the first constant voltage charging capacity. In one example embodiment, the normalized constant current charging capacity of the battery may be Q0, and the normalized constant voltage charging capacity may be about 1.3.

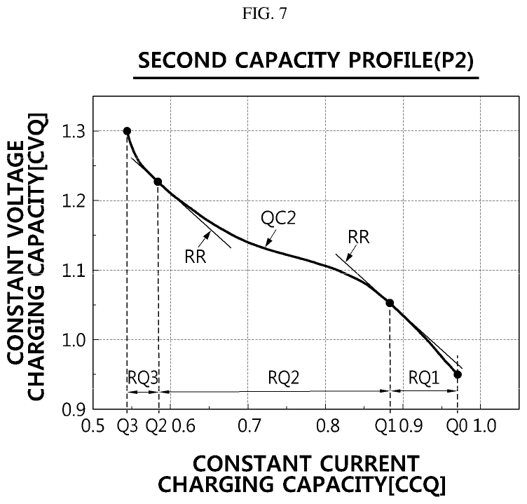

FIG. 7 is a diagram comparing a second capacity curve QC2 of the second capacity profile P2 and the reference line RR according to an embodiment of the present disclosure.

In the embodiment of FIG. 7, the second capacity curve QC2 may be a capacity curve obtained from second capacity profile P2 using a curve fitting algorithm. The second capacity curve QC2 may represent the corresponding relationship between the constant current charging capacity and the constant voltage charging capacity in the constant current charging capacity section of Q0 to Q3.

Specifically, the control unit 120 may be configured to calculate the capacity change rate for each of a plurality of constant current charging capacities included in the capacity profile. Additionally, the control unit 120 may determine a target capacity among the plurality of constant current charging capacities whose corresponding capacity change rate is the same as the reference value.

For example, in the embodiment of FIG. 7, the reference line RR with the slope of the reference value may be encountered at the Q1 point and the Q2 point in the second capacity curve QC2. That is, at the point where the constant current charging capacity is Q1 and Q2, the capacity change rate of the second capacity curve QC2 may be the same as the reference value. Therefore, the control unit 120 may determine Q1 and Q2 as a target capacity.

The control unit 120 may be configured to classify the capacity section based on the determined target capacity.

For example, in the embodiment of FIG. 7, the control unit 120 may classify Q0 to Q1 as the first capacity section RQ1, Q1 to Q2 as the second capacity section RQ2, and Q2 to Q3 as the third capacity section RQ3.

The control unit 120 may be configured to diagnose the state of the battery for the classified capacity section.

Specifically, the control unit 120 may diagnose the state of the battery for each classified capacity section. The control unit 120 may diagnose not only the current state of the battery but also the past state based on the capacity profile. That is, the control unit 120 may determine the state change pattern of the battery by diagnosing the state of the battery for each capacity section.

For example, in the embodiment of FIG. 7, the capacity change rate of the first capacity section RQ1 may exceed the reference value. Accordingly, the control unit 120 may diagnose the state of the battery in the first capacity section RQ1 as a positive electrode capacity deterioration state.

Next, the capacity change rate of the second capacity section RQ2 may be less than the reference value. Accordingly, the control unit 120 may diagnose the state of the battery in the second capacity section RQ2 as an available lithium loss state.

Finally, the capacity change rate of the third capacity section RQ3 may exceed the reference value. Accordingly, the control unit 120 may diagnose the state of the battery in the third capacity section RQ3 as a positive electrode capacity deterioration state. That is, the control unit 120 may diagnose the current state of the battery as a capacity deterioration state.

The apparatus 100 for diagnosing a battery according to an embodiment of the present disclosure has the advantage of being able to determine the state change pattern of the life cycle of the battery by specifically diagnosing the state of the battery for each capacity section. In particular, the apparatus 100 for diagnosing a battery has the advantage of being able to more efficiently collect related information that affects the change in state of the battery because it may specify the point in time when the state of the battery changes.

Meanwhile, when the state of the battery is sequentially diagnosed as a positive electrode capacity deterioration state, an available lithium loss state, and a positive electrode capacity deterioration state, the control unit 120 may be configured to diagnose the state of the battery as an unusable state.

Specifically, when the state of the battery is sequentially changed to a positive electrode capacity deterioration state, an available lithium loss state, and a positive electrode capacity deterioration state, the control unit 120 may diagnose the state of the battery as an unusable state (EOL state, End of life state). Generally, the unusable state refers to a state in which the SOH (state of health) of the battery is less than 70%, and may be a state in which disposal of the battery is recommended. If the battery in an unusable state is used continuously, there is a problem that unexpected accidents such as explosion and fire may occur.

Therefore, the apparatus 100 for diagnosing a battery has the advantage of being able to prevent unexpected accidents in advance by diagnosing the state of the battery as an unusable state when the change in state of the battery shows a certain pattern.

The control unit 120 may be configured to change a use condition preset for the battery to correspond to the state of the battery.

If the state of the battery is diagnosed as an available lithium loss state, the control unit 120 may change at least one of the upper limit of the charging C-rate preset for the battery and the rest period.

In one embodiment, the control unit 120 may reduce the upper limit of the preset charging C-rate to prevent or delay the lithium plating phenomenon in which lithium metal is precipitated on the negative electrode of the battery. For example, the control unit 120 may prevent high-rate charging of the battery by reducing the upper limit of the charging C-rate of the battery.

In one embodiment, the control unit 120 may increase the rest time set for the battery. In other words, by increasing the rest time during which the battery is maintained in an unloaded state after charging or discharging of the battery is completed, the battery may be allowed to remain in the electrical equilibrium state for a long time.

When the state of the battery is diagnosed as a positive electrode capacity deterioration state, the control unit 120 may change at least one of the upper limit voltage and the maximum allowable temperature preset for the battery.

In one embodiment, the control unit 120 may reduce the upper limit voltage and/or the maximum allowable temperature set in the battery to prevent or delay capacity deterioration of the positive electrode.

The apparatus 100 for diagnosing a battery according to an embodiment of the present disclosure has the advantage of preventing rapid deterioration of the battery by appropriately changing the use condition according to the state of the diagnosed battery.

In particular, because the apparatus 100 for diagnosing a battery may specify the point in time when the state of the battery changes, the use condition may be quickly changed to be most appropriate for the current state of the battery. Therefore, according to the apparatus 100 for diagnosing a battery, the life expectancy of the battery may be increased.

The apparatus 100 for diagnosing a battery according to the present disclosure may be applied to a battery management system (BMS). That is, the BMS according to the present disclosure may include the apparatus 100 for diagnosing a battery described above. In this configuration, at least some of components of the apparatus 100 for diagnosing a battery may be implemented by supplementing or adding functions of the components included in a conventional BMS. For example, the profile obtaining unit 110, the control unit 120 and the storage unit 130 of the apparatus 100 for diagnosing a battery may be implemented as components of the BMS.

Additionally, the apparatus 100 for diagnosing a battery according to the present disclosure may be provided in the battery pack. That is, the battery pack according to the present disclosure may include the above-described apparatus 100 for diagnosing a battery and at least one battery cell. Additionally, the battery pack may further include electrical components (relays, fuses, etc.) and a case.

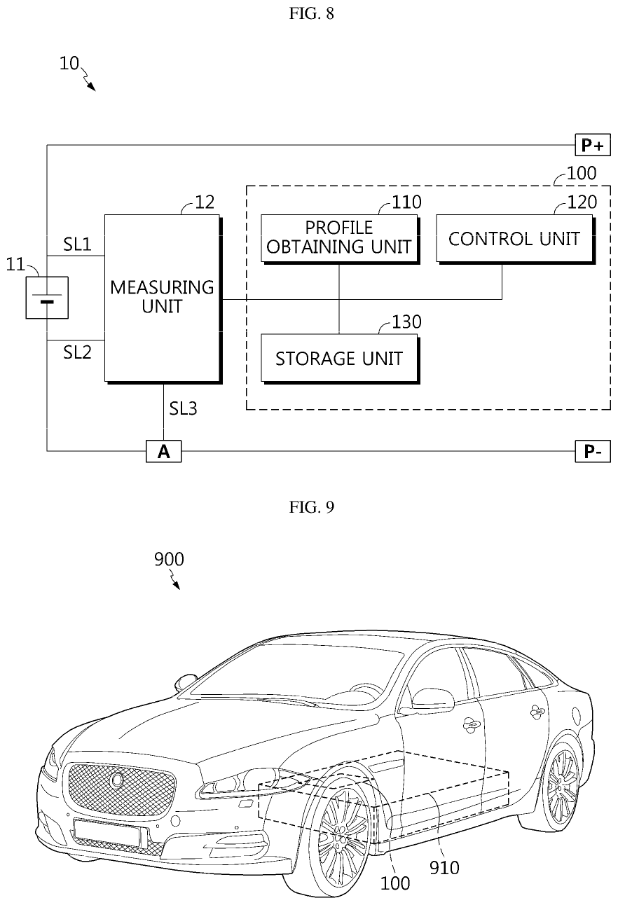

FIG. 8 is a diagram schematically showing an exemplary configuration of a battery pack 10 according to another embodiment of the present disclosure.

The positive electrode terminal of the battery 11 may be connected to the positive electrode terminal P+ of the battery pack 10, and the negative electrode terminal of the battery 11 may be connected to the negative electrode terminal P− of the battery pack 10.

The measuring unit 12 may be connected to the first sensing line SL1, the second sensing line SL2, and the third sensing line SL3. Specifically, the measuring unit 12 may be connected to the positive electrode terminal of the battery 11 through the first sensing line SL1, and may be connected to the negative electrode terminal of the battery 11 through the second sensing line SL2. The measuring unit 12 may measure the voltage of the battery 11 based on the voltage measured at each of the first sensing line SL1 and the second sensing line SL2.

Also, the measuring unit 12 may be connected to the current measurement unit A through the third sensing line SL3. For example, the current measurement unit A may be a current meter or shunt resistor that may measure the charging current and discharging current of the battery 11. The measuring unit 12 may calculate the charging capacity by measuring the charging current of the battery 11 through the third sensing line SL3. Additionally, the measuring unit 12 may calculate the discharge capacity by measuring the discharging current of the battery 11 through the third sensing line SL3.

An external device (not shown) may be connected to the positive electrode terminal P+ and the negative electrode terminal P− of the battery pack 10. For example, the external device may be a charging/discharging device or a motor of an electric vehicle that receives power from the battery 11. While the charging and discharging device is connected to the battery pack 10 and the battery 11 is being charged, the measuring unit 12 may measure the constant current charging capacity and the constant voltage charging capacity of the battery 11.

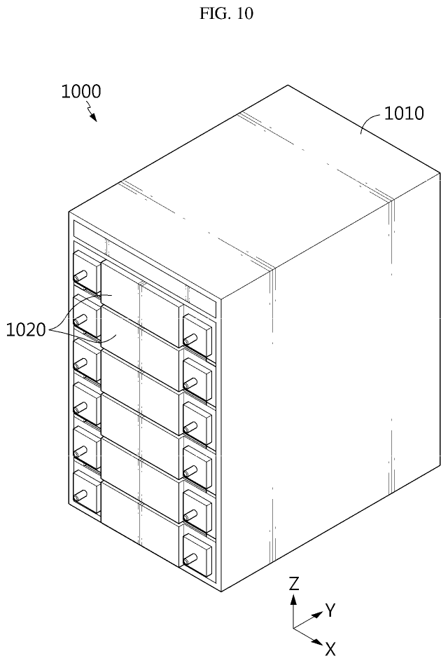

FIG. 9 is a diagram schematically showing an electric vehicle 900 according to still another embodiment of the present disclosure.

Referring to FIG. 9, the battery pack 910 according to an embodiment of the present disclosure may be included in a vehicle 900 such as an electric vehicle (EV) or a hybrid vehicle (HV). Additionally, the battery pack 910 may drive the vehicle 900 by supplying power to the motor through an inverter provided in the vehicle 900.

Also, the electric vehicle 900 may include the apparatus 100 for diagnosing a battery. For example, the apparatus 100 for diagnosing a battery is provided in the battery pack 910 and may diagnose the state of the battery pack 910 and/or each battery cell included in the battery pack 910.

FIG. 10 is a diagram schematically showing an ESS (Energy storage system) according to still another embodiment of the present disclosure.

Referring to FIG. 10, the ESS includes a plurality of rack cases 1010 and a plurality of battery modules 1020. The plurality of battery modules 1020 may be configured to be accommodated in the rack case 1010 in a vertically arranged form.

Each of the plurality of battery modules 1020 may include the apparatus 100 for diagnosing a battery. The apparatus 100 for diagnosing a battery may diagnose the state of a corresponding battery module 1020 and/or a battery cell included in the battery module 1020.

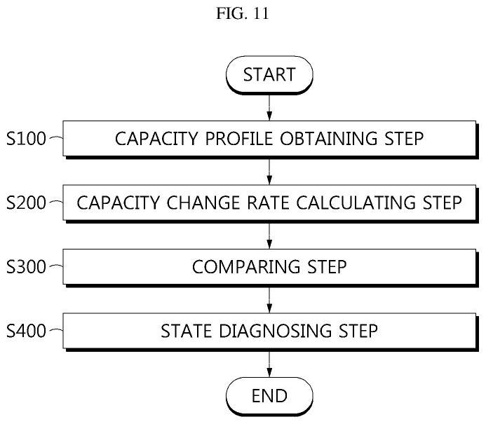

FIG. 11 is a diagram schematically showing a method for diagnosing a battery according to still another embodiment of the present disclosure.

Preferably, each step of the method for diagnosing a battery may be performed by the apparatus 100 for diagnosing a battery. Hereinafter, for convenience of explanation, the content overlapping with the previously described content will be briefly described or omitted.

Referring to FIG. 11, the method for diagnosing a battery may include a capacity profile obtaining step (S100), a capacity change rate calculating step (S200), a comparing step (S300), and a state diagnosing step (S400).

The capacity profile obtaining step (S100) is a step of obtaining a capacity profile for a constant current charging capacity and a constant voltage charging capacity measured in a charging process of a battery, and may be performed by the profile obtaining unit 110. For example, the profile obtaining unit 110 may obtain a capacity profile from the outside or the storage unit 130.

The capacity change rate calculating step (S200) is a step of calculating a capacity change rate between the constant current charging capacity and the constant voltage charging capacity in the capacity profile, and may be performed by the control unit 120.

For example, the control unit 120 may calculate the capacity change rate by calculating the ratio of the constant voltage charging capacity to the constant current charging capacity.

The comparing step (S300) is a step of comparing the calculated capacity change rate and a preset reference value, and may be performed by the control unit 120.

For example, the control unit 120 may compare the magnitudes of the calculated capacity change rate and the preset reference value.

The state diagnosing step (S400) is a step of diagnosing the state of the battery based on the comparison result, and may be performed by the control unit 120.

For example, if the capacity change rate is less than the reference value, the control unit 120 may diagnose the state of the battery as an available lithium loss state. As another example, if the capacity change rate is equal to the reference value, the control unit 120 may diagnose the state of the battery as a normal state. As another example, if the capacity change rate exceeds the reference value, the control unit 120 may diagnose the state of the battery as a positive electrode capacity deterioration state.

Meanwhile, the control unit 120 may classify the capacity profile into a plurality of capacity sections and specifically diagnose the state of the battery in each capacity section. Furthermore, the control unit 120 may diagnose the state of the battery as an unusable state when the state change of the battery shows a certain pattern (in which a positive electrode capacity deterioration state, an available lithium loss state, and a positive electrode capacity deterioration state are sequentially diagnosed).

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### Explanation of Reference Signs

10: battery pack
11: battery
12: measuring unit
100: apparatus for diagnosing a battery
110: profile obtaining unit
120: control unit
130: storage unit
900: electric vehicle
910: battery pack
1000: ESS
1010: battery rack
1020: battery module

1. An apparatus for diagnosing a battery, comprising:
a control unit configured to:
calculate a capacity change rate between a constant current charging capacity of the battery and a constant voltage charging capacity of the battery according to a capacity profile of the battery, wherein the capacity profile indicates, for each charging cycle of a plurality of charging cycles of the battery, a correspondence between the constant current charging capacity of the battery during the charging cycle and the constant voltage charging capacity of the battery during the charging cycle,
compare the calculated capacity change rate with a preset reference value, and
diagnose the state of the battery based on the comparison of the calculated capacity change rate with the preset reference value.

2. The apparatus for diagnosing a battery according to claim 1,
wherein the control unit is configured to diagnose the state of the battery as an available lithium loss state, a normal state, or a positive electrode capacity deterioration state based on the comparison of the calculated capacity change rate with the preset reference value.

3. The apparatus for diagnosing a battery according to claim 2,
wherein the control unit is configured to:
diagnose the state of the battery as the available lithium loss state, in response to the capacity change rate being less than the reference value,
diagnose the state of the battery as the normal state, in response to the capacity change rate being equal to the reference value, and
diagnose the state of the battery as the positive electrode capacity deterioration state, in response to the capacity change rate exceeding the reference value.

4. The apparatus for diagnosing a battery according to claim 2,
wherein the control unit is configured to:
classify at least one subset of the capacity profile into a respective capacity section according to a magnitude relationship between the capacity change rate and the reference value, and
diagnose the state of the battery for the respective capacity section.

5. The apparatus for diagnosing a battery according to claim 4,
wherein the control unit is configured to:
calculate the capacity change rate for each of a plurality of constant current charging capacities included in the at least one subset of the capacity profile,
select, from among the plurality of constant current charging capacities included in the capacity profile, a target capacity whose corresponding calculated capacity change rate is equal to the reference value, and
classify the subset of the capacity profile based on the selected target capacity.

6. The apparatus for diagnosing a battery according to claim 4,
wherein the control unit is configured to diagnose the state of the battery as an unusable state, in response to the state of the battery being sequentially diagnosed as the positive electrode capacity deterioration state, the available lithium loss state, and the positive electrode capacity deterioration state.

7. The apparatus for diagnosing a battery according to claim 2,
wherein the control unit is configured to change a use condition preset for the battery to correspond to the state of the battery.

8. The apparatus for diagnosing a battery according to claim 7,
wherein the control unit is configured to:
change at least one of an upper limit of a charging current rate (C-rate) preset for the battery or a rest period, in response to the state of the battery being diagnosed as the available lithium loss state, and
change at least one of an upper limit voltage or a maximum allowable temperature preset for the battery, in response to the state of the battery being diagnosed as the positive electrode capacity deterioration state.

9. The apparatus for diagnosing a battery according to claim 1,
further comprising a memory store configured to store the capacity profile,
wherein the control unit is configured to receive the capacity profile from the memory store.

10. A battery pack, comprising the apparatus for diagnosing a battery according to claim 1.

11. A method for diagnosing a battery, comprising:
obtaining a capacity profile, wherein the capacity profile indicates, for each charging cycle of a plurality of charging cycles of the battery, a correspondence between a constant current charging capacity of the battery during the charging cycle and a constant voltage charging capacity of the battery during the charging cycle;
calculating a capacity change rate between the constant current charging capacity of the battery and the constant voltage charging capacity of the battery according to the capacity profile of the battery;
comparing the calculated capacity change rate with a preset reference value; and
diagnosing the state of the battery based on the comparison of the calculated capacity change rate with the preset reference value.
